(19) United States
(12) Patent Application Publication
(10) Pub. No.: US 2020/0328102 A1
(43) Pub. Date: Oct. 15, 2020

(54) METHOD FOR DIE-LEVEL UNIQUE AUTHENTICATION AND SERIALIZATION OF SEMICONDUCTOR DEVICES

(71) Applicant: Tokyo Electron Limited, Tokyo (JP)

(72) Inventors: Anthony SCHEPIS, Albany, NY (US); Anton J. deVILLIERS, Clifton Park, NY (US); H. Jim FULFORD, Albany, NY (US)

(73) Assignee: Tokyo Electron Limited, Tokyo (JP)

(21) Appl. No.: 16/528,043

(22) Filed: Jul. 31, 2019

Related U.S. Application Data
(60) Provisional application No. 62/834,089, filed on Apr. 15, 2019.

(51) Int. Cl. H01L 21/67; H01L 23/544; H01L 21/027

(52) U.S. Cl. CPC H01L 21/67282; H01L 2223/54433; H01L 21/0274; H01L 23/544

(57) ABSTRACT

A method for marking a semiconductor substrate at the die level for providing unique authentication and serialization includes projecting a first pattern of actinic radiation onto a layer of photoresist on the substrate using mask-based photolithography, the first pattern defining semiconductor device structures and projecting a second pattern of actinic radiation onto the layer of photoresist using direct-write projection, the second pattern defining a unique identifier.

### CROSS REFERENCE TO RELATED APPLICATIONS

This application is based on and claims the benefit of and priority to U.S. Provisional Patent Application No. 62/834,089, entitled “METHOD FOR DIE-LEVEL UNIQUE AUTHENTICATION AND SERIALIZATION OF SEMICONDUCTOR DEVICES”, filed on Apr. 15, 2019, the entire contents pf which are herein incorporated by reference.

### BACKGROUND

### Technical Field

The present application relates to counterfeit control of semiconductor devices. More particularly, it relates to a method for using direct write lithography to place an optical identifier pattern at a specific location on a wafer of a semiconductor device.

### Description of the Related Art

Sales of counterfeit semiconductor devices represents a global problem costing chip makers billions of dollars each year. U.S. based chip makers alone lose over seven billion dollars per year. The Pentagon estimates that 15% of all spare and replacement chips purchased by the Pentagon are counterfeit. A disproportionate amount of the questionable chips originate from foreign countries and enter supply chains undetected. Accordingly, there is a strong desire to prevent use of counterfeit semiconductor devices.

There are many challenges and aspects to addressing the counterfeit chip problem. One fundamental capacity in fighting counterfeit sales is being able to identify counterfeit devices and/or identify authentic devices. Being able to accurately and reliably identify counterfeits is useful for removing counterfeits from commerce. Also, being able to verify authentic devices compared to total devices in the market is useful in helping quantify damages when international trade law is violated. There are some conventional systems in place to validate the authenticity/functionality of semiconductors. For example, there are standards from industry association (such as SEMI) that attempt to encrypt batch numbers from trusted manufacturers. After counterfeit devices are in the open market, however, there is little that can be done to verify integrity.

### SUMMARY

Techniques disclosed herein enable chip makers to uniquely identify their devices at the device level to provide an authentication mechanism to combat existent counterfeit devices. Techniques disclosed herein provide systems and methods that enable unique optical serialization at the die-level for chip authentication using existing or conventional semiconductor processing methods. Accordingly, economical and unique identification can be efficiently added to semiconductor manufacturing processes.

Moreover, methods disclosed herein provide unique identifiers on a die-by-die basis at the process level across multiple wafers. Conventional means of serialization do not provide such unique die-level marking. More specifically, marking herein is accomplished by using direct-write patterning systems configured to provide die-by-die unique processing. Using conventional mask-based photolithography would be cost prohibitive, while direct-write systems herein provide an economical marking solution.

In one embodiment, direct write lithography is used to place an optical identifier, for example, an alphanumeric string or a quick response (QR) code, at a specific location on a die of a wafer. In addition, mask-based exposure is used to place a circuit pattern on the die. The exposure of unique marks can occur before or after mask-based exposure. A layer of photoresist on the die is developed to generate a relief pattern which is transferred into an underlying layer. Open spaces in the underlying layer are then filled with a fill material that has a different reflectivity as compared to material of the underlying layer.

The order of the different steps as described herein is presented for clarity sake. In general, these steps can be performed in any suitable order. Additionally, although each of the different features, techniques, configurations, etc., herein may be discussed in different places of this disclosure, it is intended that each of the concepts can be executed independently of each other or in combination with each other. Accordingly, the features of the present application can be embodied and viewed in many different ways.

This summary section does not specify every embodiment and/or novel aspect of the present application. Instead, this summary only provides a preliminary discussion of different embodiments and corresponding points of novelty over conventional techniques. Additional details and/or possible perspectives of the disclosed embodiments are described in the Detailed Description section and corresponding figures of the present disclosure as further discussed below.

### BRIEF DESCRIPTION OF THE DRAWINGS

The application will be better understood in light of the description which is given in anon-limiting manner, accompanied by the attached drawings in which:

FIG. 1A is a schematic of an exemplary pattern from mask-based projection lithography applied to a set of wafers.

FIG. 1B is a schematic of an exemplary pattern from direct-write lithography applied to a set of wafers.

FIG. 2A is a schematic of an exemplary alphanumeric pattern from direct-write lithography applied to a set of dies.

FIG. 2B is a schematic of an exemplary QR code pattern from direct-write lithography applied to a set of dies.

FIG. 3 is a schematic of an exemplary apportioning of patterns from direct-write lithography applied to a set of dies.

FIG. 4 is a schematic of an exemplary cross-sectional diagram of a die-sized substrate segment with a direct write identifier process.

FIG. 5 is a schematic of an exemplary cross-sectional diagram of a die-sized substrate segment of FIG. 4 with a mask-based exposure performed after a direct write identifier process.

FIG. 6 is a schematic of an exemplary cross-sectional diagram of a die-sized substrate segment of FIG. 4 with a mask-based exposure performed first.

FIG. 7 is a schematic of an exemplary cross-sectional diagram of a die-sized substrate segment of FIG. 4 with direct write identifier process performed after a mask-based exposure.

FIG. 8 is a schematic of a relief pattern formed in the photoresist layer after completion of direct write identifier process and mask-based exposure.

FIG. 9 is a schematic of the die-sized substrate segment of FIG. 8 after transfer of the pattern of FIG. 8 into a conductive layer and filling with a film having different characteristics.

FIG. 10 shows top surfaces of several dies on a wafer.

FIG. 11 shows transfer of the combined circuit and the unique identifier pattern into a dielectric film.

FIG. 12 is a schematic of the die-sized substrate segment of FIG. 8 after transfer of the pattern of FIG. 8 into a dielectric layer and filling with a film having different characteristics.

### DETAILED DESCRIPTION OF THE PREFERRED EMBODIMENTS

Reference throughout this specification to “one embodiment” or “an embodiment” means that a particular feature, structure, material, or characteristic described in connection with the embodiment is included in at least one embodiment of the application, but do not denote that they are present in every embodiment. Thus, the appearances of the phrases “in one embodiment” or “in an embodiment” in various places throughout this specification are not necessarily referring to the same embodiment of the application. Furthermore, the particular features, structures, materials, or characteristics may be combined in any suitable manner in one or more embodiments.

Techniques herein provide methods for uniquely identifying semiconductor chips at the die level across multiple wafers and lots using conventional available semiconductor processing techniques. This includes using direct-write processing that provides die-by-die unique marking.

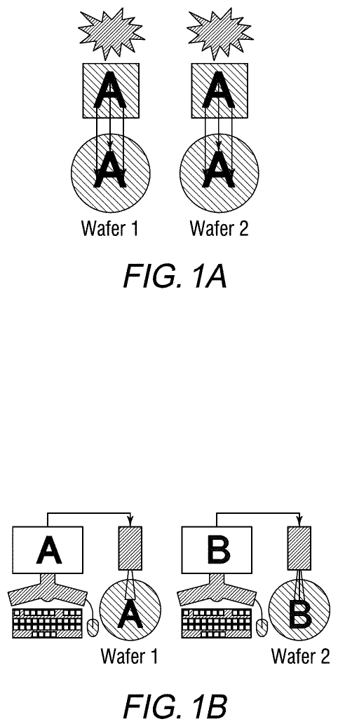

Patterning of semiconductors typically involves using an optical lithography system. Such systems use, for example, deep ultraviolet (DUV) electromagnetic radiation to create high resolution relief image patterns in a photosensitive resist material. Such relief image patterns are then used as a template for selective deposition, etch processes, and other microfabrication processing. Images realized in photoresist are projections of a master pattern on a photomask. The photomask is generally constructed of chromium and quartz, which integrate to create opaque and transparent regions that dictate the propagation of a source radiation at the mask interface. This photomask effectively defines a pattern of actinic radiation that reaches a film or layer of a photosensitive material. This creates a latent pattern within the photosensitive material by changing a solubility of the material where the pattern of light interacted with the material. The latent pattern is developed with one or more developing chemicals, which results in a relief pattern on the substrate. Although mask-based photolithography is effective, one limitation of this process is that the construction of a photomask is not trivial. Building a photomask is time-consuming and relatively expensive. Moreover, a given photomask pattern is fixed or identical for all wafers processed with that photomask. FIG. 1A illustrates a fixed pattern produced by mask-based projection lithography that is applied to a set of wafers, for example, wafer 1 and wafer 2.

Alternative mask-less patterning techniques exist that deploy direct write technology. Direct-write systems include electron beam lithography, plasmonic lithography, grating light valve lithography and digital light projection patterning systems, among others. Direct-write lithography in operation typically involves feeding a design file to a write engine. The write engine guides an exposure process to define patterns in a sensitive material based upon a coordinate grid to drive the write head(s). One advantage of direct-write systems is that exposure patterns are not restricted by physical media (such as a photomask) and are instead digitally generated. Thus, each exposure can use a different design file or modification of the design file so that each individual exposure can differ from previous and subsequent exposures. Differences can be minor or substantial. FIG. 1B illustrates how direct-write lithography can generate a different exposure pattern (for example, “A” and “B”) for different wafers (for example, wafer 1 and wafer 2). As used herein, each wafer and/or each die can contain unique information by altering information in the digital domain prior to pattern exposure.

In one non-limiting embodiment, direct write lithography is used to place an optical identifier at a specific location on a per-wafer or per-device basis in photoresist. Placement of such a unique mark can be effected as a latent pattern in photosensitive material that integrates with conventional coating/develop processes. Such a unique direct-write mark can be added without concern of physical mask (photomask) overhead because wafer pattern data is stored in the digital domain. Conventional wet or dry etch processes can then be used to transfer the serialization permanently into an underlying layer. The underlying layer can be a conductive or dielectric layer in some embodiments.

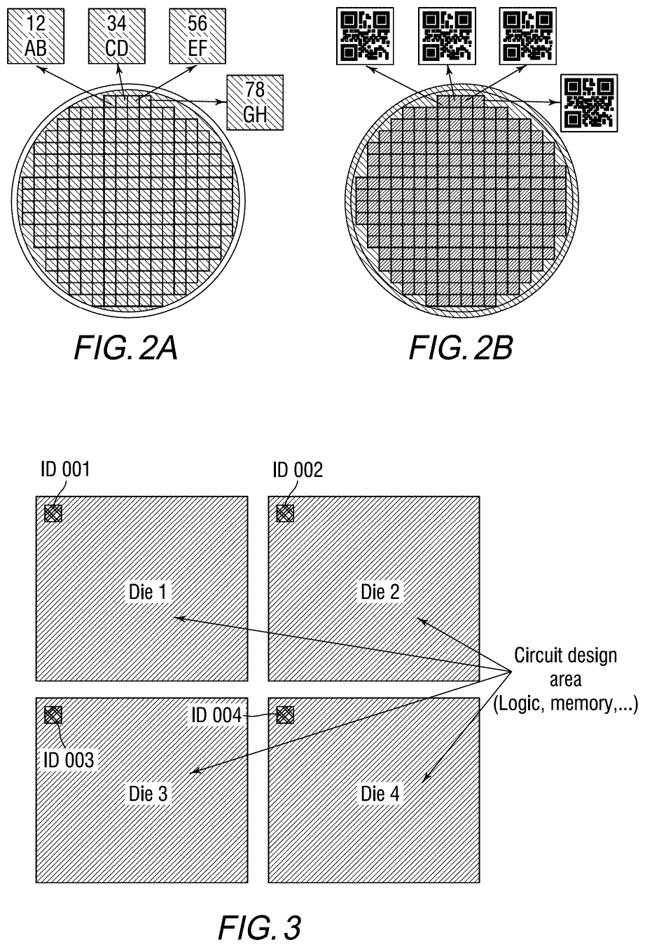

A particular type of identification string employed is selectable by each user or system controller, and or type of identification/authentication desired. By way of a non-limiting example, alpha-numeric characters can be used. An example is illustrated in FIG. 2A. Each die on the wafer can receive a unique alpha-numeric code, character string, word, et cetera. As can be appreciated, many other types of unique identifiers can be used. For example, text strings, unique pictograms, matrices, QR codes, and derivatives thereof. FIG. 2B illustrates marking each die with a unique QR code. Such unique die-level markings can be scanned by an optical microscope for reading or identification. Such unique markings can be simple or expansive with contained information. For example, a given unique identifier can be a simple serial number for each die. Alternatively, a unique identifier can include date of manufacture, chip specifications, generation of technology, origination fab, lot, et cetera.

In some embodiments, unique marking can include apportioning or designing a particular area for ID marking. FIG. 3 illustrates a typical 2×2 die recital used to scan four dies for recital fielded. Note that the bulk of the area is used for a particular circuit design. This circuit design can include placement of transistors, logic, memory, wiring, et cetera. A smaller area within the die boundaries is then designated or apportioned for unique identification marking. In this example, such areas are a small box in the upper left corner of each die (i.e., ID 001, ID 002, ID 003, ID 004).

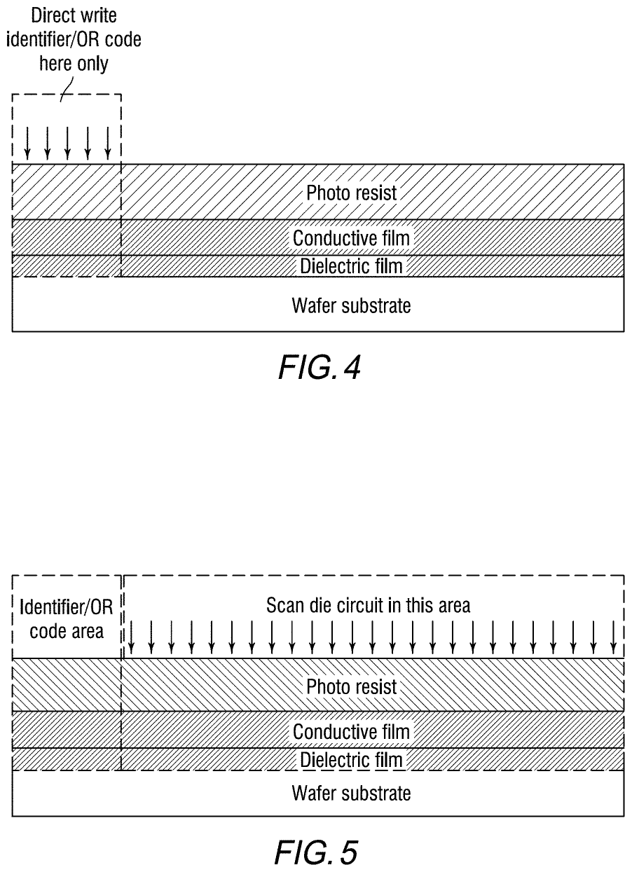

Exposure of unique marks can occur before or after mask-based exposure. For example, a wafer is prepared for lithographic exposure in a coater-developer (track) tool by coating a wafer with a photoresist film. The wafer is then ready for transport to a scanner or stepper. Prior to transfer to a scanner, the wafer can move to another tool or another module within the coater-developer for exposure of a unique mark by way of direct-write exposure. FIG. 4 shows a cross-sectional diagram of a die-sized substrate segment. The die-sized substrate segment includes a photoresist film, a conductive film and a dielectric film deposited in this order on the wafer substrate. A direct-write exposure (shown in the left side of the die) creates a latent pattern with a smaller block or area. After this direct-write exposure, the wafer can be transferred to a scanner or other mask-based photolithography system for subsequent processing. The photolithography system then exposes each die with a photomask for a particular layer pattern (for transistor shapes, contact opening, wiring, et cetera). FIG. 5 illustrates this exposure sequence. A corresponding processed wafer then has latent patterns from both a direct-write exposure as well as a mask-based exposure, and can then be developed.

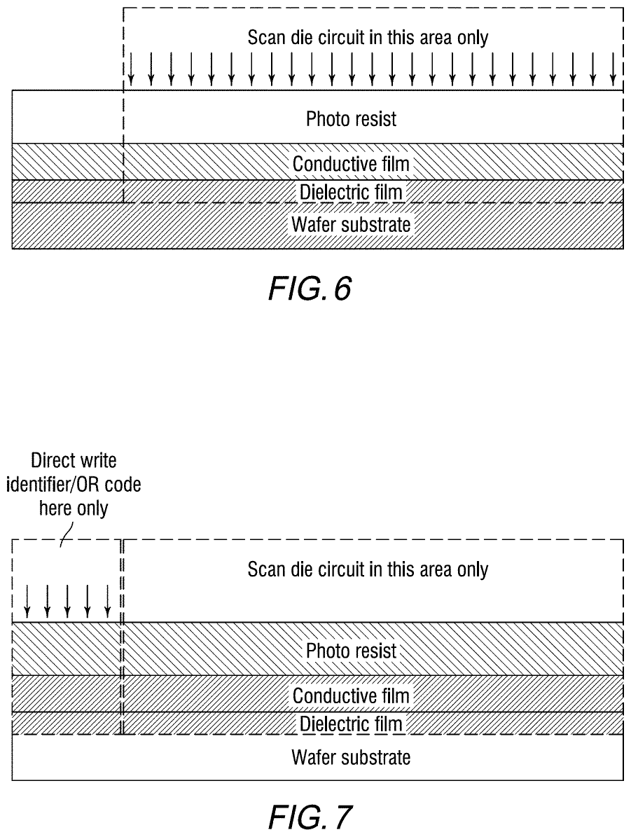

Alternatively, in another non-limiting embodiment, after a photoresist film is deposited on a wafer, the wafer is first exposed using the mask-based exposure, such as in a scanner tool (FIG. 6). Then the wafer is returned or transported to a direct-write system or module within the coater-developer for a unique ID marking exposure (FIG. 7).

It is noted that the mask-based exposure and the direct-write exposure can use a same light wavelength, or different light wavelengths. When a same light wavelength is used, then a photoresist with a single photo-acid generator (PAG) can be used. PAGs or other photo reactive components can be reactive to a narrow bandwidth of light. Accordingly, a photoresist layer can be deposited that includes two PAGs or photo-reactive compounds to create a solubility shift for each exposure wavelength.

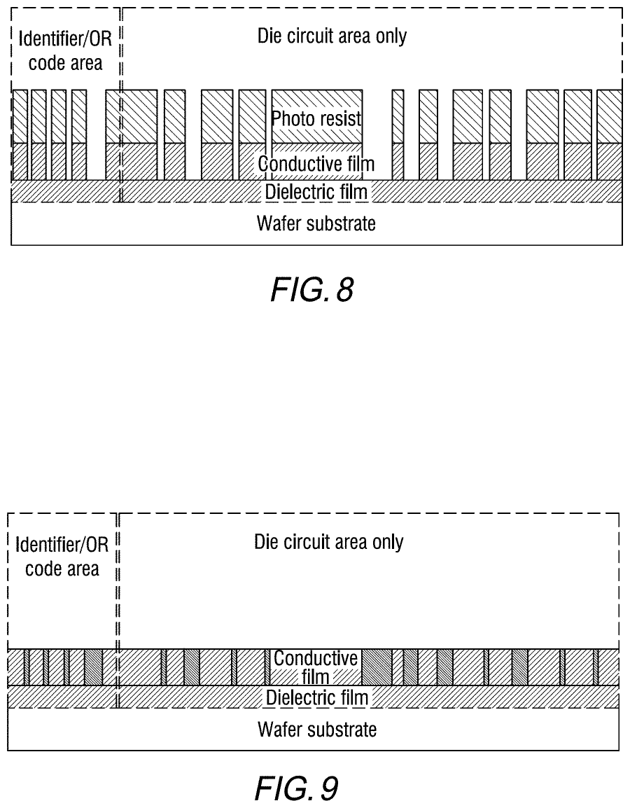

After completion of each exposure, the photoresist layer has two latent patterns, one created by mask-based exposure and one created by direct-write exposure. These patterns are then developed using one or more developing agents, depending on tone (positive/negative) of resist and type of solubility shift. The development results in a relief pattern, which can then be used as an etch mask to transfer the relief pattern into one or more underlying layers. FIG. 8 illustrates a relief pattern in the photoresist layer as well as transferring this pattern into an underlying layer. The underlying layer in this example is a conductive film.

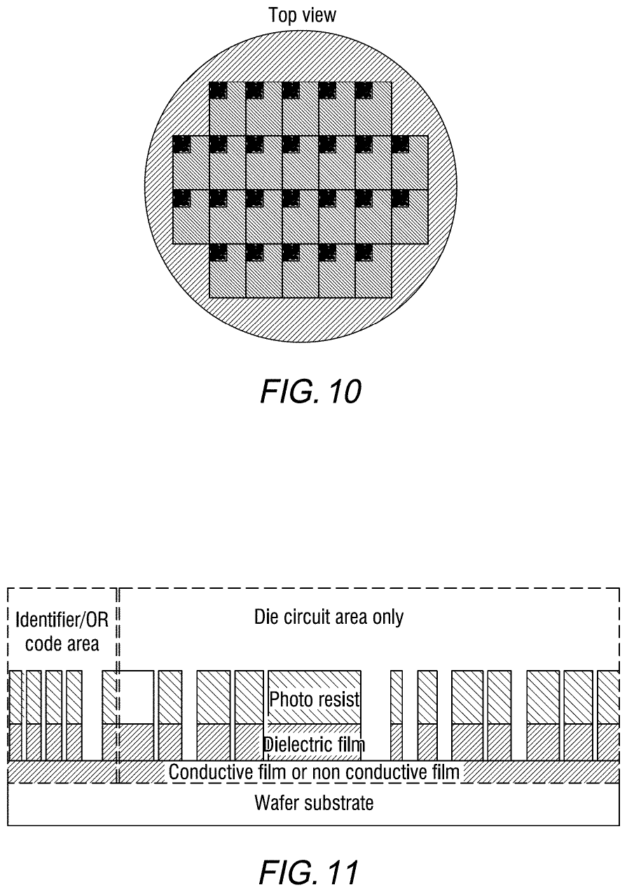

After etch transfer into the underlying film, the underlying film (such as a conductive film) can be filled with a film having a different reflectivity coefficient or other contrast characteristic. An overburden of fill can be etched back or removed by chemical-mechanical polishing. FIG. 9 illustrates an example result of such process. FIG. 10 shows a representation of top surfaces of several dies on a wafer. Each die has same circuit pattern components, but with a unique identifier (in this example a unique QR code).

In other embodiments, the order of patterning of the underlying layer can be reversed. For example, instead of transferring the combined circuit and unique identifier pattern into a conductive film, the combined pattern can be transferred into a dielectric film. FIG. 11 illustrates this etch transfer.

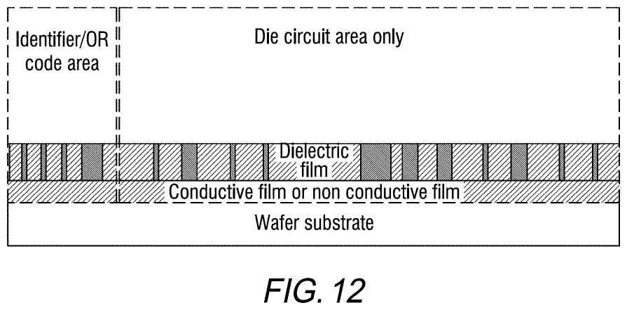

The photoresist film can then be removed. The trenches and openings in the dielectric film can then be filled with a conductor material that has a different reflectivity as compared to the dielectric, or is otherwise visually different. FIG. 12 illustrates an example result of such process.

It is noted that openings in both the unique identifier area as well as in the die circuit area can be filled with a same material. This makes microfabrication with a unique identifier enabled without adding new deposition steps or changes in materials usage. Another benefit is that there is minimal impact on throughput. For example, in embodiments, one additional exposure step in the microfabrication flow may be added. Such direct-write exposure can have high throughput. For effective marking, exposure resolutions can be lower compared to scanneephotomask resolutions. As such, unique identifiers can be exposed quickly and reliably. Throughput can be further increased when using a direct-write module positioned within a coater-developer.

Thus, a portion of a metal wiring layer can be used to create a visual, microscopic, unique identifier. Conductive material or dielectric material, used to create a given pattern, are essentially non-functional semiconductor structures, except to function as a visual identifier. Many different material combinations can be used, for example, oxide and nitride instead of conductor and dielectric, as long as the two materials can be differentiated visually or have some type of visual contrast. This contrast can be in the visual light range, or in the infrared or ultraviolet range. The unique identifier can be patterned on any given layer on a die. It can easier to visually identify the unique identifier if formed on an upper layer or top metal layer. For subsequent examination, there may be some packaging layers to remove to access a given chip. Then a microscope can be used to view or read the unique identifier to verify authenticity. The visual, unique identifier can include sufficient information to identify where the chip was made, at what time, and with which tools. A database can also be referenced to identify this detailed information based on a particular unique identifier.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same fimctional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives. Such variations are intended to be covered by the scope of this disclosure. As such, the foregoing descriptions of the embodiments are not intended to be limiting. Rather, any limitations to the embodiments are presented in the following claims.

1. A method of marking a substrate, the method comprising:
forming a layer of photoresist on a substrate;
projecting a first pattern of actinic radiation onto the layer of photoresist using a mask-based photolithography system, the first pattern defining semiconductor device structures;
projecting a second pattern of actinic radiation onto the layer of photoresist using a direct-write projection system, the second pattern defining a unique identifier;
developing the layer of photoresist to generate a relief pattern;
transferring the relief pattern into an underlying layer; and
filling open spaces in the underlying layer with a fill material that has a different reflectivity as compared to material of the underlying layer.

2. The method of claim 1, wherein the second pattern is projected subsequent to projecting the first pattern.

3. The method of claim 1, wherein the first pattern is projected subsequent to projecting the second pattern.

4. The method of claim 1, wherein the second pattern is selected from a group comprising an alpha-numeric character string, a matrix, and a pictogram.

5. The method of claim 1, wherein the fill material and the material of the underlying layer have a visual contrast.

6. The method of claim 1, wherein filling open spaces in the underlying layer results in a visual unique identifier foiiiied on a particular layer of die of a wafer.

7. The method of claim 6, wherein the second pattern defines a unique identifier so that each unique identifier is different across a wafer and set of wafers.

8. The method of claim 1, wherein the underlying layer is a conductive film or a dielectric film.

9. The method of claim 1, wherein all the open spaces in the underlying layer are filled with a same fill material.

10. The method of claim 6, wherein the visual unique identifier is formed on an upper layer or top metal layer.

11. The method of claim 6, wherein the visual unique identifier comprises information related to manufacturing location and time of the substrate.

12. The method of claim 1. wherein the projection of the first pattern and the projection of the second pattern use a same light wavelength or different light wavelengths.

13. The method of claim 1, wherein the underlying layer is an oxide film or a nitride film.

14. A method of marking a substrate, the method comprising:
forming a layer of photoresist on a substrate;
projecting a first pattern of actinic radiation onto the layer of photoresist, the first pattern defining semiconductor device structures;
projecting a second pattern of actinic radiation onto the layer of photoresist, the second pattern defining a unique identifier;
developing the layer of photoresist to generate a relief pattern;
transferring the relief pattern into an underlying layer; and
filling open spaces in the underlying layer with a fill material that has a different reflectivity as compared to material of the underlying layer.

15. The method of claim 14, wherein
the first pattern is projected using a mask-based photolithography system and the second pattern is projected using a direct-write projection system.

16. The method of claim 14, wherein
wherein the second pattern is projected subsequent to projecting the first pattern.

17. The method of claim 14, wherein the first pattern is projected subsequent to projecting the second pattern.

18. The method of claim 14, wherein the second pattern is selected from a group consisting of alpha-numeric character string, matrix, and pictogram.

19. A system for marking a substrate comprising:
a mask-based photolithography system that receives a radiation from an electromagnetic radiation system and projects a first pattern of radiation to a layer of photoresist on the substrate, the first pattern defining semiconductor device structures; and
a direct-write photolithography system that receives a radiation from the electromagnetic radiation system and projects a second pattern of radiation to the layer of photoresist on the substrate, the second pattern defining a unique identifier.

20. The system of claim 19, wherein the second pattern is selected from a group comprising an alpha-numeric character string, a matrix, and a pictogram.
